(19) United States
(12) Patent Application Publication
(10) Pub. No.: US 2014/0336961 A1
(43) Pub. Date: Nov. 13, 2014

(54) Machine, Computer Program Product for a Data-Display Device, and Method for Monitoring the Energy Use of a Machine

(71) Applicant: Robert Bosch GmbH, Stuttgart (DE)

(72) Inventors: Guenther Landgraf, Karlstadt-Karlburg (DE); Holger Schnabel, Wuerzburg (DE)

(73) Assignee: Robert Bosch GmbH, Stuttgart (DE)

(21) Appl. No.: 14/244,500

(22) Filed: Apr. 3, 2014

(30) Foreign Application Priority Data
Apr. 5, 2013 (DE) 10 2013 005 770.1

(51) Int. Cl. G01R 21/00

(52) U.S. Cl. CPC G01R 21/00
USPC 702/62

(57) ABSTRACT

A machine includes an electrical controller, a provider unit, and a communications device. The electrical controller is configured to control the machine and/or at least one element of the machine. The provider unit is configured to provide a mobile data-display device with data relating to energy use of the machine and/or of the at least one element controlled by the electrical controller. The communications device is configured for wireless communication with the mobile data-display device. The provider unit is further configured such that in response to a request received by the communications device from the mobile data-display device, the provider unit provides data currently being requested so that the mobile data-display device can read and display the provided data in real time.

This application claims priority under 35 U.S.C. §119 to patent application no. DE 10 2013 005 770.1, filed on Apr. 5, 2013 in Germany, the disclosure of which is incorporated herein by reference in its entirety.

The present disclosure relates to a machine, a computer program product for a data-display device, and a method for monitoring the energy use of a machine and/or of at least one element of said machine.

### BACKGROUND

In the field of machines such as processing machines, in particular packaging machines, printing machines etc., and machine tools, the topic of energy use is becoming increasingly important. This is why possible ways are being sought to display the energy use easily, for instance for a machine operator.

DE10 2007 062 058 A1 describes a method and a device for analyzing the energy use of a machine.

For displaying the energy use, for instance, it is also possible to provide permanently installed display screens at a central point, for example on a central computer. This is a reasonable option for a small machine that the machine operator can see clearly in full. This option is a problem, however, for a machine in which a multiplicity of machine components are installed in a production hall, as is the case, for instance, with a packaging machine, printing machine or an assembly line. For such machines, there is an increasing desire for the machine operator also to be able to determine the energy use close to the individual machine components. This would result in a multiplicity of expensive display screens, with the installation and necessary maintenance of said screens generating additional costs.

A further problem lies in the fact that at present it is not easily possible to be able to display the energy data from all the machines in a production hall. Therefore, an economic solution to this problem is required that can be handled easily and effectively by a machine operator.

### SUMMARY

The object of the present disclosure is therefore to provide a machine, a computer program product for a data-display device, and a method for monitoring the energy use of a machine and/or of at least one element of said machine, by means of which the aforementioned problems can be solved. In particular, a machine, a computer program product for a data-display device and a method for monitoring the energy use of a machine and/or of at least one element of said machine shall be provided that enable easy and economic visualization and processing of the energy use of a machine or a load.

This object is achieved by a machine as described herein. The machine comprises an electrical controller for controlling the machine and/or at least one element thereof, a provider unit for providing a mobile data-display device with data relating to the energy use of the machine and/or of at least one of the elements controlled by the electrical controller, and a communications device for wireless communication with the mobile data-display device, wherein the provider unit is designed such that in response to a request received by the communications device from the mobile data-display device, it provides the data currently being requested so that the mobile data-display device can read and display the provided data in real time.

At the machine, the energy use of the machine or of another load can be visualized and processed easily using a mobile device. For instance, the mobile device can be a smartphone, tablet PC or another device that can be connected wirelessly to a machine. The energy use can thereby be visualized easily, wirelessly and in a mobile manner. A mobile device can be used at any location, which is a major advantage particularly in a large production hall.

Using mobile devices such as a smartphone, tablet PC etc., for example, with the machine is now also possible in automation engineering. This means that the conventional wired human machine interfaces, also known as HMIs for short, are no longer required. Not only does this dispense with the installation costs of wired HMIs but it also reduces the risk of accidents from any trailing or exposed cables.

The dependent claims contain advantageous further embodiments of the device.

The provider unit is preferably designed to provide collected data relating to the energy use of the machine and/or of at least one of the elements controlled by the electrical controller, and/or to provide data analyzed by an analysis unit.

The provided data may be a history curve for detecting peaks in power.

The provided data advantageously describes the energy use for manufacturing at least one product manufactured by the machine and/or a production batch manufactured by the machine.

It is possible that the electrical controller is connected to at least one element of the machine in a machine-internal communications network in which each communications node is associated with a fixed network address, and wherein the provider unit can provide the data in association with the fixed network address.

It is also possible that the provider unit is designed to provide the data when the mobile data-display device requests the data with specification of the fixed network address.

The machine may be an automation facility in which a manufacturing process for a product or a work procedure runs in an automated manner.

Preferably, the machine or automation facility, the energy use of which is to be monitored, is part of a system for monitoring energy use. The system can additionally comprise a mobile device for displaying data relating to the energy use of the machine and/or of at least one of the elements belonging to the machine and controlled by the electrical controller of the machine.

The object is also achieved by a computer program product for a data-display device as described herein. The computer program product comprises the following steps: receiving identification data of a machine and/or of at least one element belonging to the machine and controlled by an electrical controller of the machine; using the received identification data to request, from a provider unit of the machine via a wireless communications link, data relating to the energy use of the machine and/or of at least one element belonging to the machine and controlled by the electrical controller of the machine; reading and displaying in real time on a display device of the mobile data-display device the data received as a result of the request. The computer program product offers the same advantages as previously mentioned with regard to the machine.

When executing the computer program product on the mobile data-display device, the step can additionally be executed of assigning the received identification data to a data set relating to the machine type and/or at least one type of the element belonging to the machine and controlled by the electrical controller of the machine.

When executing the computer program product on the mobile data-display device, in the receiving step, the mobile data-display device can be used to read out a code, or near-field sensor technology can be used. Hence the machine enables the use of near-field mechanisms. This means that a display using a suitable device such as, for instance, a smartphone, a tablet PC etc. is possible once the device is located within a certain radius of the machine element for which the energy use is meant to be displayed. This makes manual registration with the machine unnecessary. In this case, by near-field mechanisms, automatic registration with the machine can be achieved without entering a network address, in particular an IP address. Thus the display can also be quicker. In addition, no contact is needed between the device such as, for instance, a smartphone, a tablet PC etc. and the machine element for which the energy use is meant to be displayed.

The computer program described above can be installed on a mobile device that is used to display data relating to the energy use of a machine.

In addition, the object is achieved by a method for monitoring the energy use of a machine and/or of at least one element thereof as described herein. The method comprises the steps: using an electrical controller of the machine to control the machine and/or one element thereof, and using a provider unit to provide a mobile data-display device with data relating to the energy use of the machine and/or of at least one of the elements controlled by the electrical controller, wherein, in response to a request received by means of wireless communication from the mobile data-display device, the provider unit provides the data currently being requested so that the mobile data-display device can read and display the provided data in real time.

The method achieves the same advantages as previously mentioned with regard to the machine.

It is possible that the method additionally comprises the step of receiving identification data of a machine and/or of at least one element belonging to the machine and controlled by an electrical controller of the machine by using the mobile data-display device to read out a code or by using near-field sensor technology.

Further possible implementations of the disclosure also include combinations of features or embodiments described above or below with regard to exemplary embodiments, even if these combinations are not mentioned explicitly. A person skilled in the art will also add individual aspects as improvements or additions to the relevant basic form of the disclosure.

### BRIEF DESCRIPTION OF THE DRAWINGS

The disclosure is described in greater detail below using exemplary embodiments and with reference to the enclosed drawing, in which:

FIG. 1 shows a block diagram of a system comprising a mobile data-display device and a machine according to a first exemplary embodiment;

FIG. 2 shows a schematic diagram of part of a machine communications network of the machine according to the first exemplary embodiment;

FIG. 3 shows a schematic diagram of a method that is carried out in the system according to the first exemplary embodiment;

FIG. 4 shows a representation of an energy use of the machine, which representation can be displayed on the mobile data-display device according to the first exemplary embodiment;

FIG. 5 shows a representation of a power consumption of the machine, which representation can be displayed on the mobile data-display device according to the first exemplary embodiment;

FIG. 6 shows a representation of a history curve for power and energy monitoring, which representation can be displayed on the mobile data-display device according to a second exemplary embodiment;

FIG. 7 shows an example representation of an overview of an energy use for parts produced by the machine, according to a third exemplary embodiment.

FIG. 8 shows a block diagram of a system comprising a mobile device and a machine according to a fourth exemplary embodiment; and

FIG. 9 shows a schematic diagram of a method that is carried out in the system according to the fourth exemplary embodiment.

In the figures, elements that are identical or have the same function are denoted by the same reference signs unless otherwise stated.

### DETAILED DESCRIPTION

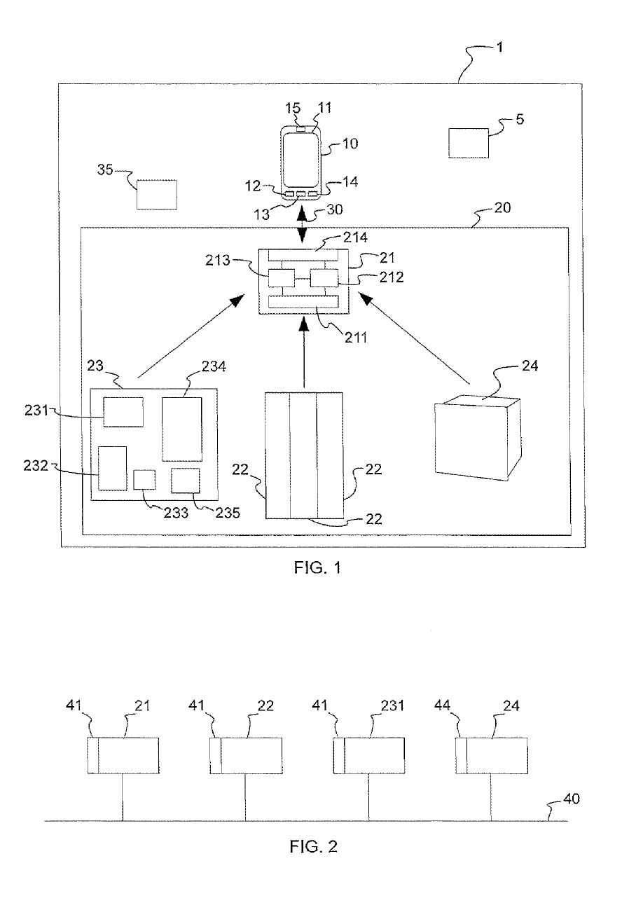

FIG. 1 shows a system 1 in which a product 5 can be manufactured and/or processed. The system 1 has a mobile data-display device 10, which is also referred to below for short as mobile device 10, and a machine 20. The device 10 and the machine 20 can communicate wirelessly with one another via a communications link 30. The wireless communication via the communications link 30 can be made, for example, by radio or optically, in particular via WLAN, Bluetooth, infrared, etc.

The mobile device 10 has a display device 11, a computer program product 12, a communications device 13, a RAM memory 14 and a reader 15. The display device 11 is used here to display visual signals, for instance in the form of images, and/or to indicate acoustic signals in the form of sounds. In addition to displaying images, the display device 11 can also be used, for example, for acoustic indication of warning messages. The computer program product 12 can also be referred to as an application or app for short. A microprocessor (not shown) of the mobile device 10 can load the computer program product 12 into the RAM memory 14 in order to execute it. The reader 15 is used for reading the data contained in a code 35, i.e. for reading out or decoding the code 35. The code 35 can be a barcode, a data matrix, a QR code, etc., for example.

The machine 20 has a central unit 21, an assembly unit 23, three drive mechanisms 22 and an energy measuring device 24. The machine 20 may be a production machine for producing or manufacturing a product, or a machine for performing a work procedure such as, for instance, cleaning an object, heating or cooling an object, positioning an object, etc. The machine may here be an automation facility in which a manufacturing process for a product or a work procedure runs in an automated manner. It is also possible, however, that manufacturing a product and carrying out a work procedure are combined in the machine 20.

The machine 20 may be, for example, a processing machine, in particular a packaging machine, printing machine, etc. The machine 20, however, may also be a machine tool such as a CNC machine, a screw-tightening assembly tool, a riveting machine etc. The machine 20 can comprise electrical, hydraulic or pneumatic loads, the energy use of which can be displayed by the display device 11 of the mobile device 10. For example, at least one of the three drive mechanisms 22 can be an electrically controlled machine, in particular a motor.

The central unit 21 in this exemplary embodiment comprises a controller 211, a provider unit 212, an analysis unit 213 and a communications device 214. The communications device 214 is used for wireless communication via the communications link 30 with the communications device 13 of the mobile device 10. The wireless communication can be made by radio or optically.

In this exemplary embodiment, the assembly unit 23 comprises five assemblies 231, 232, 233, 234, 235, which can only be switched on or off, with no other means of controlling electrically the energy use of said assemblies, which, for instance, may be a screen, an auxiliary motor for a conveyor belt, a non-controllable hydraulic pump, an actuator, etc.

The assembly unit 23 or the assemblies 231 to 235 thereof, the three drive mechanisms 22 and an energy measuring device 24 are each machine elements or elements of the machine 20.

The controller 211 controls the machine 20 and the respective drive mechanisms 22, and the individual assemblies 231 to 235 of the assembly unit 23, i.e. elements of the machine 20. The functions of the provider unit 212 and the analysis unit 213 are described in greater detail later.

The measuring device 24 can measure the power consumption and hence the energy use of, for instance, the entire machine 20. Additionally or alternatively, the energy measuring device 24 can also measure the power consumption and hence the energy use of all the drive mechanisms 22 or of one single drive mechanism 22. The energy measuring device 24 can also measure the power consumption and hence the energy use of one or all of the assemblies 231 to 235.

The machine 20 in FIG. 1 is thus a machine having an electrical drive-and-control system. For the machine 20, the energy use can be determined differently according to the type. If the drive mechanisms 22 are integral drive components, a suitable program such as Sercos Energy etc., for instance, can be used to read out the energy use directly from the drive mechanism 22. Parameters relating to the energy use of a drive mechanism 22 are hence transferred to the central unit 21 or more precisely to the provider unit 212. For external assemblies such as the assemblies 231 to 235, it is possible, for instance, to compute in the controller 211 models relating to the energy use of an assembly 231 to 235. In order to optimize the results, the energy measuring device 24 in the form of an energy meter can additionally measure all the loads/different loads.

The resultant data can be collected and processed in the central unit 21. In particular, the data is collected in the provider unit 212 and suitably analyzed and processed in the analysis unit 213. For instance, in this case, the collected data can be compared with the measured value of earlier measurements or compared with an ideal curve or ideal values. The data can then be visualized using the mobile device 10 via WLAN and the OPC classic interface, OPC/UA interface, etc. (OPC/UA=Open Productivity and Connectivity/Unified Architecture), which may be used in industrial M2M communication (M2M=Machine to Machine), and a high-level language interface, in particular MLPI (MLPI=Motion-Logic Programming Interface), NCS (numerical control interface), real-time interface for CNC control systems. Alternatively, intelligent processing of the data or further processing can take place in the computer program product 12 of the mobile device 10.

In this exemplary embodiment, the mobile device 10 can be connected by the computer program product 12 to the central unit 21, and can read out and visualize locally in real time the energy currently being used. In this case, the energy use and/or power consumption can be displayed for any number of drive mechanisms 22 and/or assemblies 231 to 235. The mobile device 10 is likewise able to form sub-assemblies and to display the energy use of said sub-assemblies live, i.e. in real time.

Real time in this sense means that the energy use values are read out and visualized using a time span acceptable to the system 1. The time span lies approximately in the range in which conditions change in the system 1. The time span may lie in the region of milliseconds, for instance, depending on the system.

FIG. 2 shows a machine communications network 40, to which are connected the central unit 21, the drive mechanisms 22 and the assembly unit 23. More precisely, with regard to the assembly unit 23, the individual assemblies 231 to 235 are each individually connected to the machine communications network 40.

In FIG. 2, for the sake of simplicity, only the central unit 21, the assembly 231, one drive mechanism 22 and the energy measuring device 24 are shown and connected to the machine communications network 40. For the purpose of identifying the individual communications nodes such as the assembly 231, the drive mechanism 22, the energy measuring device 24 etc., each communications node has a fixed network address. In FIG. 2, the central unit 21 has a first fixed network address 41. The drive mechanism 22 has a second fixed network address 43. The assembly 231 has a third fixed network address 42. The energy measuring device 24 has a fourth fixed network address 44. The other components or elements of the machine 20 that are shown in FIG. 1 likewise have a fixed network address in the machine communications network 40, or the data is collected from a node having a fixed network address, even though these nodes are not each shown in FIG. 2. The elements need not necessarily have a fixed network address, however. For example, according to a modification of the configuration described above, the energy measurement from the energy measuring device can be evaluated via an analog input of the controller or of the drive system.

The fixed network addresses 41, 42, 43, 44 can be mounted on the drive mechanism 22, the respective assembly 231 to 235 and/or the energy measuring device 24 in the form of the code 35 such that they can be read by the mobile device 10. If the mobile device 10, using the computer program product 12 and/or the reader 15 and the code 35, reads in a fixed network address, then identification data for the machine 20 or the respective machine element 21, 22, 231 to 235, 24 is available to the mobile device. The computer program product 12 can use this identification data to request from the machine 20 and more precisely from the provider unit 212 thereof, data about the power consumption and/or energy use of the machine 20 or the machine element 21, 22, 231 to 235, 24 that is identified by the identification data.

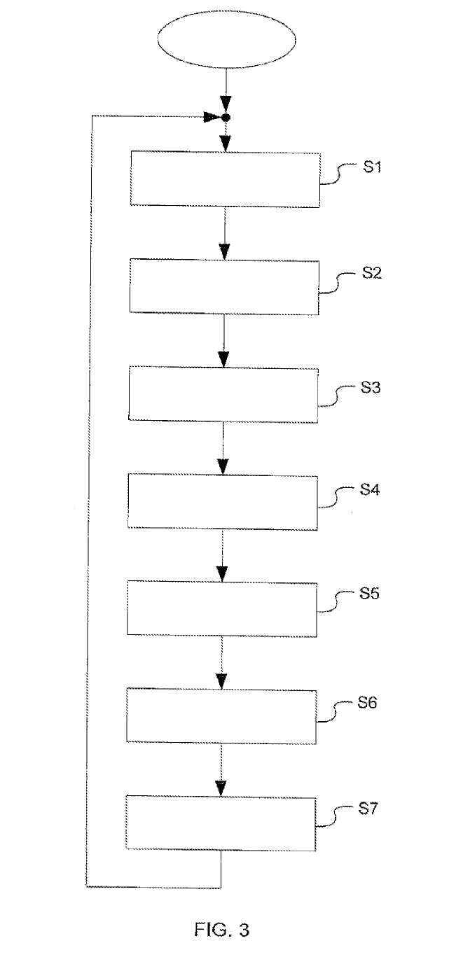

FIG. 3 shows a method that is carried out in the system 1 for monitoring the energy use of the machine 20 and/or at least of the central unit 21, of one of the drive mechanisms 22 and/or of assemblies 231 to 235 and/or of the energy measuring device 24, i.e. one of the elements of the machine 20.

After the method is started, in a step S1, the machine 20 and/or one of its elements 22, 231 to 235, 24 is controlled by the electrical controller 211 of the machine 20. In addition, the computer program product 12 can be started on the mobile device 10. The computer program product 12 can also be started later, however. Then the method flow proceeds to a step S2.

In the step S2, the provider unit 212 is used to provide the mobile device 10 with data relating to the energy use of the machine 20 and/or of at least one of the elements 22, 231 to 235, 24 controlled by the electrical controller 211. In this step, the provider unit 212 can provide the data in particular continually or also only intermittently, in particular each time after a predetermined time period has elapsed. The provider unit 212 can store the data, for instance. Then the method flow proceeds to a step S3.

In the step S3, the data provided by the provider unit 212 can be analyzed in the analysis unit 213. In this step, for instance, the energy use in Wh can be calculated from the power consumption in W of the machine 20. Then the method flow proceeds to a step S4.

In the step S4, by reading out the code 35, the mobile device 10 receives identification data of the machine 20 and/or of at least one element 22, 231 to 235, 24 controlled by the electrical controller 211 of the machine 20. In this exemplary embodiment, the identification data is the network address 41 to 44 of one of the elements 21, 22, 231 to 235, 24. In this step, the received or read-in identification data is assigned to a data set relating to the machine type and/or at least one type of the element 22, 231 to 235, 24 belonging to the machine 20 and controlled by the electrical controller 211 of the machine 20. Then the method flow proceeds to a step S5.

In the step S5, the mobile device 10 requests, via the communications link 30 from the provider unit 212 and/or the analysis unit 213, the data relating to the energy use of the machine 20 and/or of at least one element 22, 231 to 235, 24 belonging to the machine 20 and controlled by the electrical controller 211 of the machine 20, the identification data of which element and/or of the machine 20 was received in step S4. Then the method flow proceeds to a step S6.

In the step S6, in response to the request received in step S5 from the mobile data-display device 10 by means of wireless communication, the provider unit 212 and/or the analysis unit 213 provides the data currently being requested. In this step, the data is provided such that the mobile data-display device 10 can read and display the provided data in real time. Then the method flow proceeds to a step S7.

In the step S7, the data requested in the step S5 from the provider unit 212 and/or the analysis unit 213 is displayed in real time on the display device 11 of the mobile device 10. If applicable, a warning message is output by the acoustic indication device 14. Then the method flow returns to the step S1.

The method is at least partially completed if the machine 20 is switched off and/or execution of the computer program product 12 on the mobile device 10 is stopped.

Hence, if in the step S1 or later, the computer program product 12 is loaded into the RAM memory 14 of the mobile device 10, once it is loaded, the preceding steps S4, S5 and S7 can be performed by the mobile device 10.

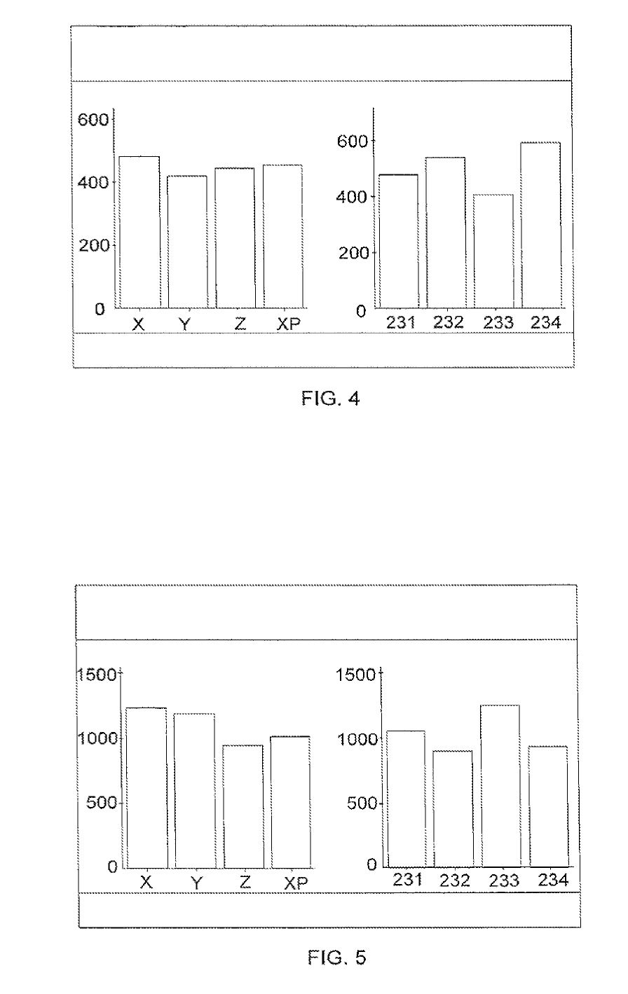

FIG. 4 shows an example of a display on the display device 11 of the mobile device 10 for a case in which the energy use in Wh is displayed for the axes X, Y, Z and XP, which are controlled by the drive mechanisms 22. In this example, XP stands for the print roller of a printing machine. In addition, the right-hand half of FIG. 4 shows the energy use in Wh for the assemblies 231 to 234.

FIG. 5 shows an example of a display on the display device 11 of the mobile device for a case in which the power consumption in W is displayed for the axes X, Y, Z and XP, which are controlled by the drive mechanisms 22. In this example, XP again stands for the print roller of a printing machine. In addition, the right-hand half of FIG. 5 shows the power consumption in W for the assemblies 231 to 234.

The mobile device 10 can hence be connected by the computer program product 12 to the central unit 21, which may be a control system and/or drive system, as previously described.

According to a second exemplary embodiment, the computer program product 12 can use the display device 11 of the mobile device 10 to determine and display, in addition to the live data, also the corresponding history curve of the power or energy of individual elements of the machine 20, of sub-assemblies of these individual elements or of the entire machine 20. FIG. 5 shows an example of this.

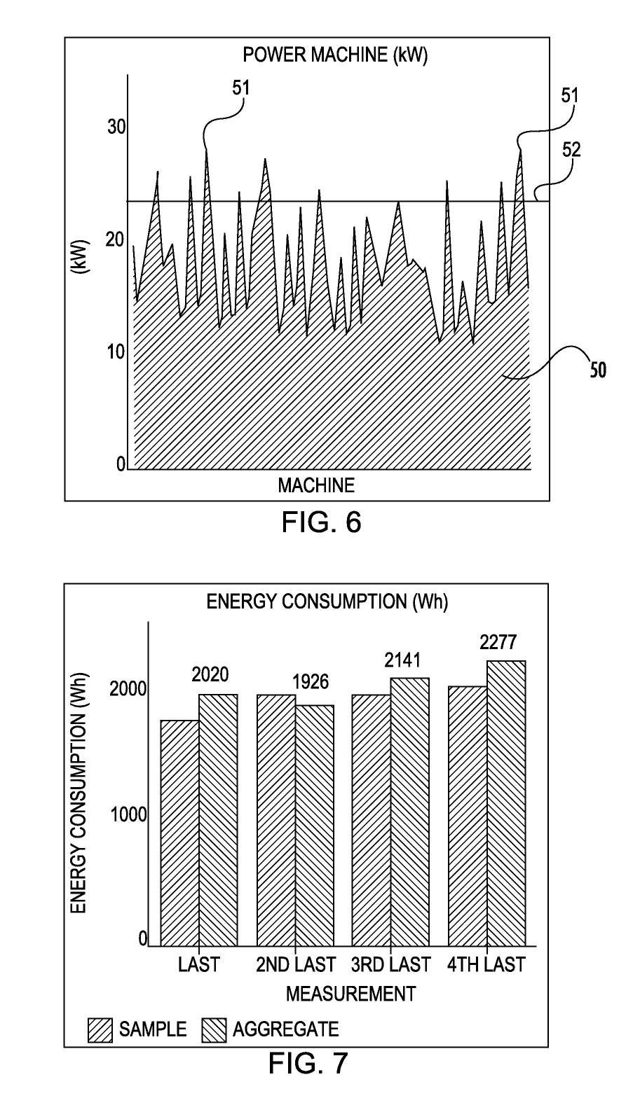

FIG. 6 shows a possible display for a history curve 50 relating to the energy use of the machine 20 or of one of the elements 21, 22, 231 to 235, 24 thereof according to the second exemplary embodiment. The representation shown in FIG. 6 can be used to detect peaks 51 in power of the machine 50. For the sake of clarity, a reference sign has not been assigned to all the peaks in power in FIG. 6. Optionally, the computer program product 12 detects peaks 51 in power within defined limits 52, and sends warning messages, information by SMS etc. to defined users so that these users can respond to peaks 51 in power.

According to a third exemplary embodiment, using the computer program product 12, the display device 11 of the mobile device 10 can display the energy use for the parts last produced by the machine 20. FIG. 7 shows an example of this.

For the display in FIG. 7, the energy use is calculated in the central unit 21, in particular in the analysis unit 213 and/or the controller 211. Alternatively, the energy use can also be calculated on the mobile device 10, in particular using the computer program product 12. Again in this exemplary embodiment, the energy use can be subdivided into a plurality of energy groups, such as drive mechanisms 22 and assemblies 231 to 235 in this example. In addition to determining the energy use for just one produced part, the energy use can also take place over a specific production batch or a complete production run, for example all the parts to be produced for a customer order. In web-processing machines, the energy use can be determined over a specific length. For instance, in this case, the energy use for the last 10 kilometers of printed material can be collected and visualized. Alternatively, the energy use of an entire job can be determined and visualized, and can be included in the job costing, for example.

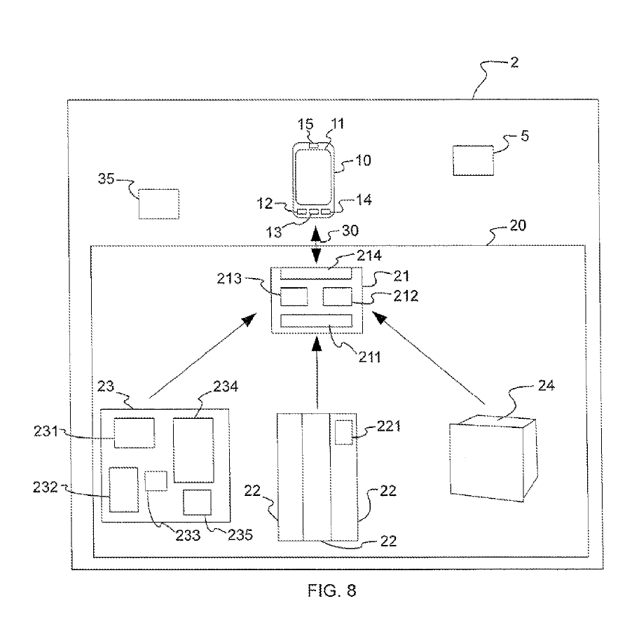

FIG. 8 shows a system 2 comprising a mobile device 10 and a machine 20 according to a fourth exemplary embodiment. The system 2 largely has the same design and function as the system 1 according to the previous exemplary embodiments. Therefore only the differences from the previous exemplary embodiments are described below.

In this exemplary embodiment, at least one of the drive mechanisms 22 is equipped with near-field sensor technology 221. Using the near-field sensor technology 221, the particular energy use of the drive mechanism 22 located in the immediate vicinity is displayed to a user if the user comes within the range of the near-field sensor technology 221 of the drive mechanism 22 or passes said technology. In this case, near-field sensor technology means a sensor technology that enables the use of the mobile device 10 to detect the drive mechanism 22 or the identification data thereof in a range of approximately 0.01 m to 20 m, for example in a range of approximately 3 to 10 m, for the drive mechanism 22, in particular in front of or around said drive mechanism.

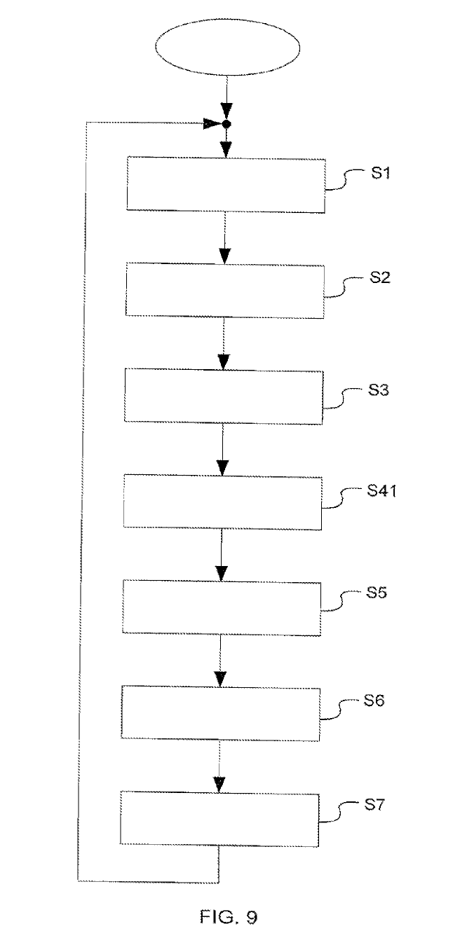

FIG. 9 shows a method that is carried out in the system 2 for this exemplary embodiment. Thus, in the system 2, a step S41 is carried out instead of the step S4 in the previous exemplary embodiments.

In the step S41, the near-field sensor technology 221 is used to receive identification data of the machine 20 and/or of at least one element 22, 231 to 235, 24 belonging to the machine 20 and controlled by an electrical controller 211 of the machine 20. The method carried out in the system 2 is otherwise identical to the method carried out in the system 1 according to the previous exemplary embodiments.

Hence, a user can move freely with the mobile device 10 in a production hall. For complete freedom, all elements of the machine 20 are preferably equipped with near-field sensor technology 221. Thus, only one mobile device 10 is required inside a production hall to monitor the energy use of the entire machine 20.

According to the exemplary embodiments described above, energy monitoring, which is also referred to as load monitoring, can be performed at the machine 20 using the mobile device 10 in the form of a smart device such as a smartphone, tablet PC etc. Energy monitoring is carried out by the mobile device 10 being connected wirelessly to a control system, drive system or server, which in the preceding exemplary embodiments is the central unit 21. The types of connection can be implemented, for example, using a standardized OPC classic, OPC/UA interface etc. or using a high-level language interface, in particular MLPI, NCS etc.

For all the exemplary embodiments described above, energy data can be displayed in real time locally on the mobile device 10. Alternatively or additionally, the history curve of a subsystem can be visualized on the mobile device 10, as described with reference to the second exemplary embodiment. Alternatively or additionally, in all the exemplary embodiments described above, the energy use of produced parts can be calculated and displayed as described with reference to the third exemplary embodiment.

All the embodiments described above of the systems 1, 2, of the mobile device 10, the machine 20 and the method can be used individually or in any possible combinations. In particular, all the features and/or functions of the exemplary embodiments described above can be combined in any way. In addition, the following modifications are possible in particular.

The parts shown in the figures are represented schematically and in the precise embodiment can differ from the forms shown in the figures, provided the above-described functions of said parts are guaranteed.

In an extended embodiment of the disclosure, the computer program product 12 can visualize simultaneously the power consumption and/or the energy use of a plurality of machines 20. In such a case, the system 1 or the system 2 has more than one machine 20. Nevertheless, just one mobile device 10 is still used. As described above, the mobile device 10 can communicate with the machine 20 wirelessly again in this case. Hence, the mobile device 10 does not need to be connected by cable to the machine 20 for visualization to take place.

As described with reference to the first exemplary embodiment, the fixed network addresses 41, 42, 43, 44 in the code 35 in the form of a barcode, a data matrix, a QR code etc. can be mounted on the drive mechanism 22, the respective assembly 231 to 235 and/or the energy measuring device 24 such that they can be read by the mobile device 10. This code can contain the IP address which the computer program product 12 uses for connection and then for being able to display the energy use of the machine. Optionally, it is likewise possible that each energy user of the machine 20 carries this identification. Thus, the computer program product 12 can also connect to an individual energy user of the machine 20, which energy user can be accessed via wireless data transmission (WLAN, Bluetooth, infrared etc.).

The code 35 can assume different forms for the different elements of the machine. For instance, the code 35 for one element may be a QR code, whereas the code 35 for another element is a barcode. Any other variants are possible.

In the methods according to FIG. 3 and FIG. 9, other method sequences are also possible. For example, the step S3 of analyzing the data can be omitted. The step S3 can also be executed by the computer program product 12 of the mobile device. In addition, it is also possible that the step S3 is executed after the step S4 or the step S5. Alternatively, the step S3 can also be executed in parallel with at least the step S4.

What is claimed is:

1. A machine comprising:
an electrical controller configured to control the machine and/or at least one element of the machine;
a provider unit configured to provide a mobile data-display device with data relating to energy use of the machine and/or energy use of the at least one element of the machine; and
a communications device configured to wirelessly communicate with the mobile data-display device,
wherein the provider unit is further configured such that in response to a request received by the communications device from the mobile data-display device, the provider unit provides data currently being requested so that the mobile data-display device can read and display the provided data in real time.

2. The machine according to claim 1, wherein the provider unit is further configured to provide collected data relating to the energy use of the machine and/or the energy use of the at least one element of the machine, and/or to provide data analyzed by an analysis unit.

3. The machine according to claim 2, wherein the provided data includes a history curve for detecting peaks in power.

4. The machine according to claim 2, wherein the provided data describes an energy use for manufacturing at least one product manufactured by the machine and/or a production batch manufactured by the machine.

5. The machine according to claim 1, wherein:
the electrical controller is connected to the at least one element of the machine in a machine-internal communications network in which each communications node is associated with a fixed network address, and
the provider unit is further configured to provide data in association with the fixed network address.

6. The machine according to claim 5, wherein the provider unit is further configured to provide the data when the mobile data-display device requests the data with specification of the fixed network address.

7. The machine according to claim 5, wherein the machine is an automation facility in which a manufacturing process for a product or a work procedure runs in an automated manner.

8. The machine according to claim 1, wherein:
a system is configured to monitor the energy use of the machine or the energy use of an automation facility, and
the system includes the machine and a mobile device configured to display data relating to the energy use of the machine and/or of the at least one element of the machine.

9. A method configured to be executed by a computer program product on a mobile data-display device, the method comprising:
receiving identification data of a machine and/or of at least one element belonging to the machine and controlled by an electrical controller of the machine;
using the received identification data to request, from a provider unit of the machine via a wireless communications link, data relating to energy use of the machine and/or energy use of the at least one element belonging to the machine and controlled by the electrical controller of the machine; and
reading and displaying in real time on a display device of the mobile data-display device the data received as a result of the request.

10. The method according to claim 9, further comprising:
assigning the received identification data to a data set relating to the machine type and/or at least one type of the at least one element belonging to the machine and controlled by the electrical controller of the machine.

11. The method according to claim 9, wherein in the receiving step, the mobile data-display device is used to read out a code, or near-field sensor technology is used.

12. The method according to claim 9, wherein:
a mobile device is configured to display data relating to the energy use of a machine, and the computer program product is configured to be installed on the mobile device.

13. A method of monitoring energy use of a machine and/or of at least one element of the machine, comprising:
using an electrical controller of the machine to control the machine and/or the at least one element of the machine; and
using a provider unit to provide a mobile data-display device with data relating to the energy use of the machine and/or of the at least one of the element of the machine,
wherein, in response to a request received by wireless communication from the mobile data-display device, the provider unit provides the data currently being requested so that the mobile data-display device can read and display the provided data in real time.

14. The method according to claim 13, further comprising:
receiving identification data of the machine and/or of the at least one element of the machine by using the mobile data-display device to read out a code or by using near-field sensor technology.
